(19) United States
(12) Patent Application Publication
(10) Pub. No.: US 2011/0186937 A1
(43) Pub. Date: Aug. 4, 2011

(54) ADJUSTMENT OF TRANSISTOR CHARACTERISTICS BASED ON A LATE WELL IMPLANTATION

(76) Inventors: Thilo Scheiper, Dresden (DE); Sven Beyer, Dresden (DE); Jan Hoentschel, Dresden (DE); Andy Wei, Dresden (DE)

(21) Appl. No.: 12/914,343

(22) Filed: Oct. 28, 2010

(30) Foreign Application Priority Data
Jan. 29, 2010 (DE) 10 2010 001 404.4

(51) Int. Cl. H01L 29/78; H01L 21/336; H01L 21/8234

(52) U.S. Cl. 257/402; 438/289; 438/276; 257/E21.409; 257/E21.618; 257/E29.255

(57) ABSTRACT

A self-aligned well implantation process may be performed so as to adjust threshold voltage and/or body resistance of transistors. To this end, after removing a placeholder material of gate electrode structures, the implantation process may be performed on the basis of appropriate process parameters to obtain the desired transistor characteristics. Thereafter, any appropriate electrode metal may be filled in, thereby providing gate electrode structures having superior performance. For example, high-k metal gate electrode structures may be formed on the basis of a replacement gate approach, while the additional late well implantation may provide a high degree of flexibility in providing different transistor versions of the same basic configuration.

### BACKGROUND OF THE INVENTION

1. Field of the Invention

The present disclosure generally relates to integrated circuits, and, more particularly, to the highly sophisticated integrated circuits including transistor structures of different threshold voltages.

2. Description of the Related Art

The manufacturing process for integrated circuits continues to improve in several ways, driven by the ongoing efforts to scale down the feature sizes of the individual circuit elements. A key issue in developing integrated circuits of increased packing density and enhanced performance is the scaling of transistor elements, such as MOS transistor elements, to increase the number of transistor elements in order to enhance performance of modern CPUs and the like with respect to operating speed and functionality. One important aspect in manufacturing field effect transistors having reduced dimensions is the reduction of the length of the gate electrode that controls the formation of a conductive channel separating the source and drain regions of the transistor. The source and drain regions of the transistor element are conductive semiconductor regions including dopants of an inverse conductivity type compared to the dopants in the surrounding crystalline active region, which may also be referred to as a substrate or a well region.

Although the reduction of the gate length is necessary for obtaining smaller and faster transistor elements, it turns out, however, that a plurality of issues are additionally involved to maintain proper transistor performance for a reduced gate length. For example, so-called short channel effects may occur for highly scaled transistor elements, resulting in a reduced controllability of the channel region, which may result in increased leakage currents and generally in degraded transistor performance. One challenging task in this respect is, therefore, the provision of appropriately designed junction regions in the form of shallow junctions, at least at the area in the vicinity of the channel region, i.e., source and drain extension regions, which nevertheless exhibit a moderately high conductivity so as to maintain the resistivity in conducting charge carriers from the channel to a respective contact area of the drain and source regions at a relatively low level, while the parasitic drain/source capacitance and the electric field are also to be taken into consideration. The requirement for shallow junctions having a relatively high conductivity while providing adequate channel control is commonly met by performing an ion implantation sequence on the basis of a spacer structure so as to obtain a high dopant concentration having a profile that varies laterally and in depth. The introduction of a high dose of dopants into a crystalline substrate area, however, generates heavy damage in the crystal structure and, therefore, one or more anneal cycles are typically required for activating the dopants, i.e., for placing the dopants at crystal sites, and to cure the heavy crystal damage. However, the electrically effective dopant concentration is limited by the ability of the anneal cycles to electrically activate the dopants. This ability in turn is limited by the solid solubility of the dopants in the silicon crystal and the temperature and duration of the anneal process that are compatible with the process requirements. Moreover, besides the dopant activation and the curing of crystal damage, dopant diffusion may also occur during the annealing, which may lead to a “blurring” of the dopant profile. This effect may be advantageous in some cases for defining critical transistor properties, such as the overlap between the extension regions and the gate electrode and also for reducing the overall capacitance of the PN junctions by increasing the depth of the deep drain and source areas, for instance, in silicon-on-insulator (SOI) devices, the drain and source areas may extend down to the buried insulating layer with a desired high concentration. Therefore, for highly advanced transistors, the positioning, shaping and maintaining of a desired dopant profile are important properties for defining the final performance of the device, since the overall series resistance of the conductive path between the drain and source contacts, as well as the controllability of the channel region, may represent a dominant aspect for determining the transistor performance.

Moreover, other important transistor characteristics may presently also be adjusted on the basis of the complex dopant profile in the active regions of the transistor elements. For example, the threshold voltage of a transistor, i.e., the voltage applied between the gate electrode and the source terminal of the transistor element, at which a conductive channel forms in the channel region, is a transistor characteristic that substantially affects overall transistor performance. Typically, the ongoing shrinkage of critical dimensions of the transistors may also be associated with a continuous reduction of the supply voltage of electronic circuitry. Consequently, for performance driven transistor elements, the corresponding threshold voltage may also have to be reduced in order to obtain a desired high saturation current at a reduced gate voltage, since the reduced supply voltage may also restrict the available voltage swing for controlling the channel of the transistor. However, the reduction of the threshold voltage, which may be typically accomplished by appropriately doping the well region of the transistor, in combination with sophisticated halo implantation processes, which are designed to provide the appropriate dopant gradient at the PN junctions and for the overall conductivity of the channel region, may also affect the static leakage currents of the transistors. That is, by lowering the threshold voltage, typically, the off current of the transistors may increase, thereby contributing to the overall power consumption of an integrated circuit, which may comprise millions of corresponding transistor elements. In addition to increased leakage currents caused by extremely thin gate dielectric materials, the static power consumption may result in unacceptable high power consumption, which may not be compatible with the heat dissipation capabilities of integrated circuits designed for general purposes. In an attempt to maintain the overall static leakage currents at an acceptable level, complex circuitries are typically designed so as to identify speed critical paths and selectively form transistors of the speed critical paths so as to have a low threshold voltage, while less critical signal paths may be realized on the basis of transistors of higher threshold voltages, thereby reducing static leakage currents while, however, also reducing switching speed of these transistors. For example, in modern central processing units (CPUs), several different “flavors” of transistors may be employed in order to take into consideration the different hierarchy with respect to signal processing speeds.

For example, generally, high performance transistors, i.e., transistors having a very thin gate dielectric material, may thus be implemented with different transistor characteristics depending on the overall circuit layout and design. For instance, the different transistor characteristics may result in devices differing in gate leakage, off-current, threshold voltage and the like. Typically, these different characteristics may be implemented on the basis of an appropriate implantation regime when incorporating the well dopant species prior to patterning the gate electrode structures. Hence, the well dopant implantation sequence for N-channel transistors and P-channel transistors may be performed such that a well implantation may provide a basic well dopant concentration, which may be considered as a regular well dopant profile, while any other “flavors” may then be established by performing any further well implantation processes based on the same or a counter-doping species, thereby increasing or reducing the overall conductivity in the corresponding well regions. Thereafter, the processing is continued in the same manner for any of these different transistor versions so as to comply with the various design requirements with respect to implementing transistors of different characteristics. The different well dopant profiles, however, may also have a negative effect on the transistors, since, for instance, each version of the basically same transistor configuration may have implemented therein a different dopant concentration, which may thus result in a difference in the body resistance. That is, the semiconductor region positioned between the drain and source regions and below the actual channel region has received a different dopant concentration for the different transistor versions, which may negatively affect device operation. However, the different well dopant concentrations are also provided in the areas in which the drain and source regions are subsequently provided and may, thus, also have an influence on the finally obtained transistor characteristics, in particular when the drain and source dopant concentration has to be reduced due to a further reducing of overall transistor dimensions, which typically requires a reduced spacer width and, thus, a reduced lateral offset from the channel region and body region of the transistor. In particular, SOI transistors may suffer from reduced transistor performance, since the deep drain and source areas may not efficiently connect to the buried insulating layer due to the presence of the well dopant species. That is, upon implanting the drain and source dopant species and annealing the devices for inducing a certain degree of dopant diffusion, a significantly reduced drain and source dopant concentration may connect to the buried insulating layer, thereby possibly increasing the overall junction capacitance of the transistor. Upon further reducing the overall drain and source dopant concentration due to further device scaling, this undesired effect may be even further pronounced, as the well dopant concentration may not be reduced in order to obtain the desired threshold voltage characteristics. Consequently, providing a plurality of different flavors or versions of transistors of basically the same configuration may become increasingly difficult in highly scaled semiconductor devices, in particular if sophisticated circuit designs may demand an even further increased number of different transistor flavors.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which transistor characteristics may be adjusted on the basis of a late implantation process, during which a desired well dopant species may be incorporated in a locally restricted manner. To this end, the drain and source areas of the transistor may be covered by any appropriate material, such as a portion of an interlayer dielectric material and the like, while at least a portion of the gate electrode may be removed in order to form a gate opening or gate trench, through which the well dopant species may be incorporated in a very localized manner, substantially without affecting the deep drain and source areas. By applying an appropriate masking regime, characteristics of transistors having basically the same configuration may be adjusted with a high degree of flexibility, for instance by adjusting the threshold voltage and the body resistance in a highly decoupled manner so that even sophisticated design requirements in view of providing transistors of different characteristics may be met. In some illustrative aspects disclosed herein, the concept of a late self-aligned well implantation may be combined with so-called replacement gate approaches, in which an electrode metal, possibly in combination with a work function metal, may be provided after completing the basic transistor configuration. In this manner, a very efficient overall process may be achieved.

One illustrative method disclosed herein comprises forming a gate electrode structure of a transistor on a semiconductor region, wherein the gate electrode structure comprises a placeholder electrode material. The method further comprises forming drain and source regions in the semiconductor region and removing at least a portion of the placeholder electrode material so as to form a gate opening in the gate electrode structure. Additionally, the method comprises introducing a dopant species into the semiconductor region through the gate opening and forming an electrode metal in the gate opening.

A further illustrative method disclosed herein comprises forming a first gate electrode structure above a first semiconductor region and forming a second gate electrode structure above a second semiconductor region of a semiconductor device, wherein the first and second gate electrode structures comprise a placeholder electrode material. The method further comprises forming a first gate opening in the first gate electrode structure by removing at least a portion of the placeholder electrode material in the first gate electrode structure. Moreover, a second gate opening is formed in the second gate electrode structure by removing at least a portion of the placeholder electrode material in the second gate electrode structure. The method additionally comprises introducing dopant species into at least one of the first and second semiconductor regions through at least one of the first and the second gate openings. Additionally, an electrode metal is filled into the first and second gate openings.

One illustrative semiconductor device disclosed herein comprises a gate electrode structure of a transistor formed on a semiconductor region, wherein the semiconductor region has a first length. Additionally, drain and source regions are formed in the semiconductor region and a body region is formed in the semiconductor region and laterally separates the drain and source regions. Moreover, an implantation region is formed in the semiconductor region by a specific dopant species and has a second length that is less than the first length.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of a semiconductor device during various manufacturing stages, in which a late self-aligned well implantation may be performed through a gate opening, according to illustrative embodiments;

FIGS. 1e-1f schematically illustrate cross-sectional views of the semiconductor device according to illustrative embodiments in which a sacrificial material may be removed so as to expose drain and source areas after performing the later well implantation;

FIGS. 2a-2b schematically illustrate cross-sectional views of a semiconductor device in which gate openings or trenches may be formed in separate etch processes, wherein intermediately a well implantation may be performed, according to illustrative embodiments; and

FIGS. 3a-3e schematically illustrate cross-sectional views of a semiconductor device during various manufacturing stages, in which a plurality of gate openings may be provided in a common etch sequence, followed by a masked late well implantation, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides manufacturing techniques and semiconductor devices in which a well dopant species, for instance for threshold adjustment and/or body resistance adjustment, may be formed in a locally restricted manner through a gate opening or trench, which may be obtained after removing at least a portion of the gate material, such as polysilicon, silicon/germanium and the like. In this manner, the well dopant species may be incorporated in a self-aligned manner, independent of the lateral dimensions of the gate opening, so that transistor characteristics, such as threshold voltage, body resistance and the like, may be efficiently adjusted substantially without affecting the dopant concentration in the drain and source regions. Furthermore, if required, the threshold voltage and the body resistance may be adjusted in a highly decoupled manner, since the type of dopant species and the implantation energy may be appropriately selected so as to position a desired type and concentration of a well dopant species at any appropriate depth within the semiconductor region. The incorporation of the well dopant species in the drain and source regions may be suppressed by providing any appropriate material laterally adjacent to the gate electrode structure, for instance in the form of a portion of an interlayer dielectric material or by providing a sacrificial material, if the drain and source regions have to be accessed in a later manufacturing stage, for instance, for incorporating a metal silicide material, if desired.

In some illustrative embodiments, the gate openings may then be filled with an appropriate metal-containing material, for instance in order to provide a work function material, in combination with an actual electrode metal, wherein a high-k dielectric material may also be provided, for instance, prior to patterning the gate electrode structures, or a high-k dielectric material may be formed after removing the placeholder electrode material, depending on the overall process strategy. Consequently, the late well dopant implantation may be efficiently combined with providing sophisticated gate electrode structures, for instance comprising a high-k dielectric material in combination with a metal electrode material, so that overall process complexity of any such replacement gate approaches may not be unduly increased by the late self-aligned well implantation.

As a consequence, a plurality of different transistor characteristics of transistors having otherwise substantially the same configuration may be established substantially without negatively affecting the drain and source dopant profiles, for instance in view of connecting to a buried insulating material at the bottom of the active region, while the degree of counter-doping in the drain and source region due to additional well dopants may also be reduced.

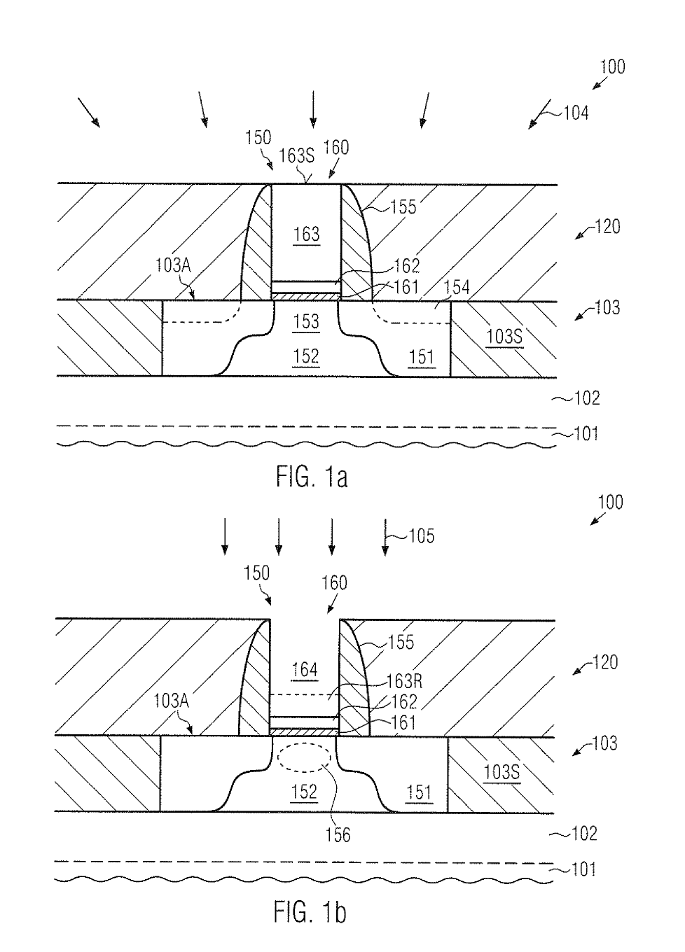

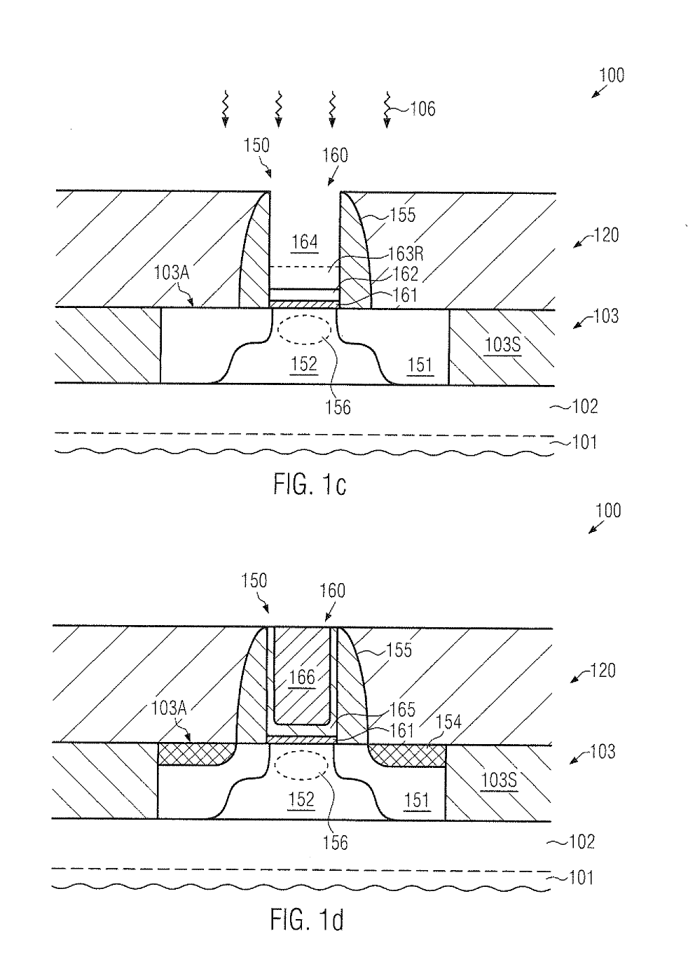

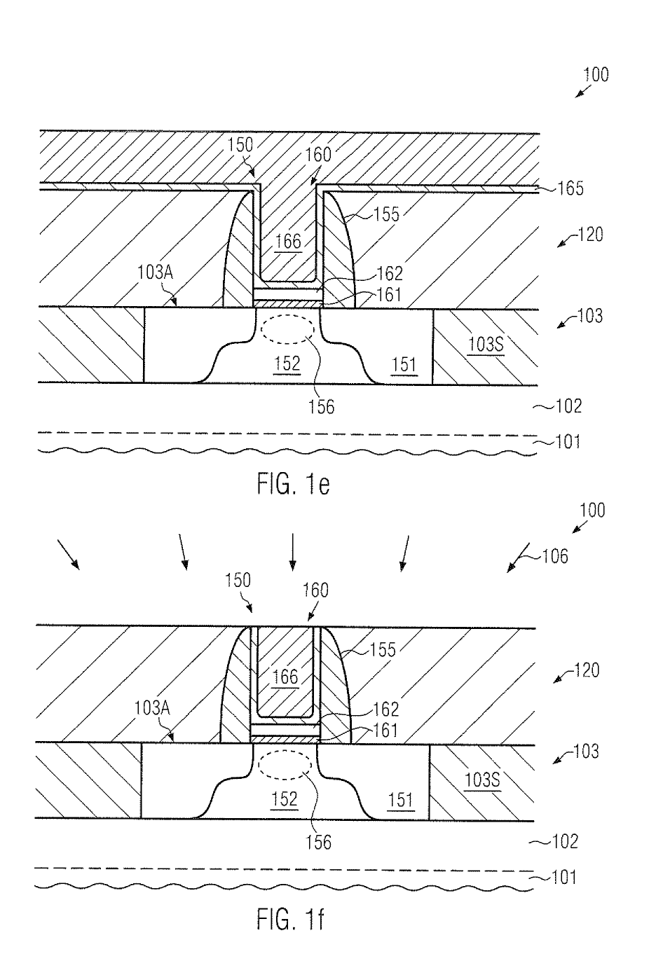

FIG. 1a schematically illustrates a cross-sectional view of a semiconductor device 100 comprising a substrate 101, above which may be formed a semiconductor layer 103. Moreover, in the embodiment shown, a buried insulating layer 102 may be provided between the semiconductor layer 103 and the substrate 101, thereby forming an SOI configuration. The semiconductor layer 103 may initially represent any appropriate semiconductor material for forming therein and thereabove transistors, such as a transistor 150. Presently, most complex integrated circuits are fabricated on the basis of a silicon material and, thus, the semiconductor layer 103 may represent a silicon-based material, which may also have incorporated therein other components, such as germanium, carbon and the like, in order to obtain the desired electronic characteristics. It should be appreciated, however, that the semiconductor layer 103 may be composed of any appropriate semiconductor material, as required. Furthermore, in the manufacturing stage shown, the semiconductor layer 103 may have formed therein a plurality of isolation structures 103S, for instance provided in the form of shallow trench isolations, thereby laterally delineating active regions, wherein, for convenience, a single active region 103A is illustrated in FIG. 1a. Thus, a length of the active region 103A, i.e., in FIG. 1a, the horizontal extension of the active region 103A, may be defined by the isolation structure 103S, and similarly a width of the active region 103A, i.e., in FIG. 1a, a direction perpendicular to the drawing plane of FIG. 1a, may also be determined by the isolation structure 103S. An active region is generally to be understood as a semiconductor region in which PN junctions are to be provided for one or more transistors, wherein, in the example shown in FIG. 1a, a single transistor may be formed in and above the active region 103A, while, in other cases, two or more transistor elements may be formed in the same active region, depending on overall design requirements. The transistor 150 may comprise a gate electrode structure 160 comprising a gate dielectric material 161, possibly in combination with an appropriate cap layer 162, followed by an electrode material 163, which may also be referred to as a placeholder electrode material, since at least a portion of the material 163 may be removed and replaced by a metal-containing electrode material. For example, the material 163 may be provided in the form of a polysilicon material, a silicon/germanium mixture and the like. In some illustrative embodiments, the gate dielectric material 161 may comprise a high-k dielectric material, for instance in the form of hafnium oxide, zirconium oxide, hafnium silicon oxide and the like, wherein a high-k dielectric material is generally to be understood as a material having a dielectric constant of 10.0 or higher.

Generally, a high-k dielectric material may be advantageous in increasing the capacitive coupling between the gate electrode structure 160 and a channel region 153 positioned in the active region 103A below the gate dielectric material 161. It is well known that, upon reducing the channel length of a field effect transistor, the capacitive coupling may also have to be increased, which has been accomplished by reducing a thickness of the gate dielectric material 161. However, upon providing transistor elements having a gate length of approximately 80 nm and less, the resulting thickness of a silicon dioxide based material, which has been used as a gate dielectric due to the superior characteristics of a silicon/silicon dioxide interface, may have to be selected to be less than two nanometers, which may result in significant leakage currents, which may no longer be acceptable for many types of complex integrated circuits. For this reason, a high-k dielectric material may replace at least a portion of the conventional silicon dioxide based dielectric material, thereby providing a desired high capacitive coupling based on a physically greater thickness compared to a silicon dioxide material. Thus, in some illustrative embodiments, a high-k dielectric material, possibly in combination with a very thin conventional dielectric material, may be provided in the gate dielectric material 161. In other cases, however, the gate dielectric material 161 may represent a conventional dielectric material, which, if desired, may be replaced in a later manufacturing stage, at least partially, by a high-k dielectric material. Furthermore, in many approaches, in which a high-k dielectric material may be provided in an early manufacturing stage, a metal-containing cap material, such as the cap layer 162, may be provided, for instance in the form of titanium nitride and the like, thereby appropriately encapsulating the sensitive high-k dielectric material in the gate insulation layer 161. In some illustrative embodiments, the gate dielectric material 161 and/or the conductive cap layer 162 may comprise an additional metal species for appropriately adjusting the work function of the gate electrode structure 160, at least for certain transistors, if required.

The gate electrode structure 160 may be laterally enclosed by a spacer structure 155, which may have any appropriate configuration so as to ensure integrity of the gate electrode structure 160 and to act as an implantation mask for defining the lateral and vertical dopant profile of drain and source regions 151 formed in the active region 103A. Furthermore, a body region 152 may be formed laterally between the drain and source regions 151 and may be positioned below the channel region 153, wherein the body region 152 is to be understood as a portion of the active region 103A having an inverse doping compared to the drain and source regions 151, thereby forming corresponding PN junctions, in particular at the bottom of the active region 103A. It should be appreciated that additional counter-doped regions, so-called halo regions, may be provided at any appropriate position within the active region 103A in order to provide the desired junction characteristics, for instance in view of dopant gradient and the like. For convenience, any such additional counter-doped regions are not shown in FIG. 1a. Furthermore, in some illustrative embodiments, as indicated by dashed lines, metal silicide regions 154 may already be formed in the drain and source regions 151, while, in other embodiments, as will be explained later on in more detail, such metal silicide regions, if required, may be formed in later manufacturing stage. Additionally, the semiconductor device 100 may comprise, in this manufacturing stage, a mask layer 120, which may represent a portion of an interlayer dielectric material of a contact level, which may receive contact elements connecting to a metallization system in a later manufacturing stage. In other illustrative embodiments, the mask layer 120 may represent a sacrificial material, such as a silicon dioxide material and the like, which may be removed in a later manufacturing stage, when, for instance, the metal silicide regions 154 are still to be formed in the drain and source regions 151 and/or when one or more additional implantation processes are to be performed for establishing the desired dopant concentration in the drain and source regions 151.

The semiconductor device 100 as illustrated in FIG. 1a may be formed on the basis of the following processes. The isolation structure 103S may be formed on the basis of any well-established manufacturing technique, i.e., forming trenches in the semiconductor layer 103 and filling the same with any appropriate material, such as silicon dioxide, silicon nitride and the like. By forming the isolation structures 103S, the lateral dimensions of the active region 103A are also defined. Prior to or after providing the isolation structure 103S, a basic well doping process may be performed, if required, in order to adjust the conductivity type of the transistor 150, the basic body resistance of the region 152 and the like. It should be appreciated that a corresponding well implant may be performed so that this may be appropriate for the plurality of different “flavors” of transistors of the same conductivity type, since the desired final characteristics may be adjusted on the basis of a late well implantation, as will be described later on in more detail. Moreover, in some illustrative embodiments, the basic well dopant implantation may be omitted in this manufacturing stage, when the desired characteristics may be established by one or more late well implantation processes only. In this case, a very low dopant concentration may be established in the active region 103A or the active region may be provided as a substantially undoped semiconductor material, wherein the desired dopant concentration in the channel region 153 and the body region 152 may be established on the basis of the late well implantation, thereby avoiding any counter-doping of the drain and source regions 151. Next, the gate electrode structure 160 may be formed by any appropriate process strategy. For example, as discussed above, the gate dielectric material 161 may be formed so as to comprise a high-k dielectric material, possibly in combination with a conventional silicon dioxide based material that may provide superior interface characteristics, if required. Thereafter, the conductive cap layer 162, for instance in the form of titanium nitride and the like, may be provided, possibly in combination with a work function metal species, such as aluminum, lanthanum and the like. Next, the placeholder material 163 may be deposited, for instance in the form of amorphous silicon and the like, which may be accomplished by applying the established deposition recipes. Furthermore, any additional materials, such as dielectric cap layers, hard mask materials and the like, may be provided according to process and device requirements. Next, sophisticated lithography and etch techniques may be applied to form the gate electrode structure 160. Thereafter, any sidewalls thereof may be protected by appropriate spacer elements (not shown), followed by an implantation process for forming a first portion of the drain and source regions 151. Thereafter, the spacer structure 155 may be formed in accordance with any appropriate process technique, and subsequently a further implantation process may be applied so as to provide the basic dopant concentration of the drain and source regions 151. In some illustrative embodiments, an anneal process or a process sequence may be performed so as to activate the dopant species and also provide a certain degree of dopant diffusion in order to obtain the desired lateral and vertical profile of the drain and source regions 151. As previously explained, since any increased concentration of a well dopant species in the drain and source regions 151 may be avoided, a corresponding appropriate connection with a buried insulating later 102 may be accomplished, thereby obtaining the desired PN junction characteristics. In other illustrative embodiments, one or more anneal processes may be performed in a later manufacturing stage, i.e., after incorporating a well dopant species in a highly localized manner.

Next, the mask layer 120 may be provided, for instance by depositing one or more dielectric materials and planarizing the same in order to expose a surface 163S of the placeholder material 163. In other illustrative embodiments, prior to depositing the mask layer 120, the metal silicide regions 154 may be formed on the basis of any appropriate process technique. In this case, the material 120 may be provided in the form of an interlayer dielectric material, which may comprise any appropriate material system, such as silicon nitride, in combination with silicon dioxide and the like. It should further be appreciated that, in some illustrative embodiments, the material 120, or at least a portion thereof, may be provided in the form of a highly stressed material, thereby generating a desired type of strain in the channel region 153, which may increase charge carrier mobility in the channel region 153, thereby efficiently enhancing performance of the transistor 150. In other cases, the material 120 may be provided in the form of any sacrificial material, such as a silicon dioxide material and the like, which may also be planarized so as to expose the surface 163S. Next, the device 100 may be exposed to a reactive etch ambient 104, which may be established on the basis of any appropriate selective etch chemistry for removing the material 163 or at least a portion thereof selectively with respect to the spacer structure 155 and the mask material 120. For example, a plurality of wet chemical etch recipes, for instance based on TMAH (tetra methyl ammonium hydroxide) and the like, are available, or any plasma assisted etch recipes, possibly in combination with wet chemical etch processes, may be applied.

FIG. 1b schematically illustrates the semiconductor device 100 in a further advanced manufacturing stage, in which a gate opening or trench 164 may be provided in the gate electrode structure 160 due to removal of at least a portion of the placeholder material 163 as shown in FIG. 1a. For example, the gate opening 164 may extend to the cap layer 162 or to the gate dielectric material 161, depending on the overall process strategy. In other cases, a portion 163R of the placeholder material may be preserved, if considered appropriate for the further processing of the device 100, for instance in terms of preserving integrity of the underlying materials, wherein the portion 163R may be removed in a later manufacturing stage, if required. Consequently, the gate opening 164 may represent an appropriate implantation mask so as to incorporate the desired well dopant species in a locally restricted manner into the active region 103A.

During an implantation process 105, an appropriate dopant species, in combination with appropriate implantation parameters, may be selected so as to generate an implantation region 156 in a locally restricted manner, wherein a depth of the vertical extension and the dopant concentration of the implantation region 156 may be efficiently adjusted on the basis of the process parameters of the process 105. For example, the implantation region 156 may be positioned below the electrically effective channel that may form in the channel region 153 (FIG. 1a) upon operating the device 100, which may, thus, enable efficiently adjusting the desired threshold voltage for an otherwise given configuration of the transistor 150. Moreover, if desired, an additional implantation process may be performed to appropriately adjust the conductivity and, thus, resistance of the body region 152 by selecting appropriate process parameters. In other cases, the implantation region 156 may be positioned at the bottom of the active region 103A, thereby providing a desired body resistance in the region 152, without significantly affecting the threshold voltage of the transistor 150, which may be adjusted on the basis of a basic well doping performed in an earlier manufacturing stage, as previously discussed. On the other hand, a significant penetration of the drain and source regions 151 by the dopants of the implantation region 156 may be suppressed due to the self-aligned nature of the implantation process 105. It should be appreciated that the implantation region 156 may be considered as being laterally restricted in the sense that at a height level in which a maximum concentration of a specific dopant species forming the region 156 may be positioned, a significant drop of concentration may be observed when moving towards the isolation structure 103S. That is, due to the masking effect obtained by the gate opening 164, significant penetration of the drain and source regions 151 during the implantation process 105 may be avoided, thereby generating a dopant profile for the region 156, which may at least be laterally restricted in the sense that a corresponding maximum concentration may drop at least by approximately 50% within the drain and source regions 151.

FIG. 1c schematically illustrates the semiconductor device 100 according to some illustrative embodiments in which an anneal process 106 may be applied so as to further enhance the efficiency of the implantation region 156. It should be appreciated that generally the incorporation of the dopant species for the implantation region 156 may be accomplished on the basis of a moderately low implantation dose, for instance compared to the drain and source regions 151, since here generally a significantly lower dopant concentration is required, wherein the region 156 may, in some cases, be considered as a region for “fine-tuning” the transistor characteristics, while a basic well doping may have been incorporated in an early manufacturing stage. Consequently, corresponding crystal damage may be low and the degree of activation of the dopant species as implanted may be considered appropriate. In other cases, the anneal process 106 may be performed on the basis of process parameters, which may result in a specific desired degree of dopant diffusion, while, in other cases, dopant activation and re-crystallization may be taken into account, while dopant diffusion is to be suppressed. For this purpose, a plurality of well-established anneal techniques, such as rapid thermal anneal and the like, are available, while, in other cases, flashlight-based or laser-based anneal techniques may provide extremely short exposure times, thereby reducing dopant diffusion, if required. In some illustrative embodiments, the anneal parameters may be selected such that a significant effect on other device areas, such as any metal silicide materials formed in the drain and source regions 151, as indicated above in FIG. 1a, may be contained at a low level. In still other illustrative embodiments, the anneal process 106 may be performed so as to concurrently obtain the desired final dopant profile for the drain and source regions 151, which may still be in a substantially amorphized state, if the preceding anneal processes have been omitted.

It should be appreciated that the residual material 163R, if preserved, may result in superior integrity of any underlying materials during the treatment 106, if considered appropriate.

Thereafter, the further processing may be continued, for instance by removing any further materials, such as the residual material 163R, if still present, the layer 162 and the layer 161, or at least a portion thereof, depending on the overall process strategy. In other cases, the layer 162 may be preserved, at least partially, when the material 161 may represent a high-k dielectric material or may at least include any such material so as to comply with the desired characteristics of the gate electrode structure 160. Next, any appropriate material or material system may be deposited, for instance for providing a high-k dielectric material, if required, a work function metal species, such as titanium nitride, aluminum, lanthanum, tantalum and the like, and providing an electrode metal, such as aluminum and the like. To this end, any appropriate deposition techniques, such as chemical vapor deposition (CVD), physical vapor deposition, electrochemical deposition or any combination thereof may be applied.

FIG. 1d schematically illustrates the semiconductor device 100 in a further advanced manufacturing stage. As illustrated, the gate electrode structure 160 may comprise a metal electrode material 166, such as aluminum and the like, possibly in combination with a work function metal species 165, such as lanthanum, aluminum, titanium nitride, tantalum and the like. In the embodiment shown, the work function metal species 165 may be formed on the gate dielectric material 161, which, as previously explained, may comprise a high-k dielectric material. In other cases, the cap layer 162 (FIG. 1c) may still be present, at least partially, depending on a resulting work function of the gate electrode structure 160. Furthermore, as illustrated, the metal silicide regions 154, if required, may be formed in the drain and source regions 151. The metal materials or metal-containing materials 165 and 166 may be formed on the basis of any appropriate deposition technique, as described above, and thereafter any excess material may be removed, for instance on the basis of chemical mechanical polishing (CMP) and the like.

Consequently, the transistor 150 may have a desired basic configuration, i.e., a target gate length and transistor width in combination with a specified dopant profile of the drain and source regions 151, wherein an additional adjustment of transistor characteristics, such as threshold voltage, body resistance and the like, may be accomplished by the implantation region 156, which may be positioned in the body region 152 and may not extend across the entire length of the active region 103A due to the previous locally restricted implantation process.

With reference to FIGS. 1e-1f, illustrative embodiments will now be described, in which the material 120 (FIG. 1d) may be removed after filling in an appropriate electrode metal.

FIG. 1e schematically illustrates the device 100, wherein the material layers 165 and 166 are formed in the gate electrode structure 160 and above the mask layer 120. Furthermore, in this embodiment, the conductive cap layer 162 may at least be partially preserved during the preceding process flow, when the combination of the materials 165 and 162 may provide the appropriate work function of the gate electrode structure 160. In other cases, the material 162 may be removed, as is also explained above. Furthermore, in the embodiment shown, any metal silicide regions may not yet be formed in the drain and source regions 151, if any heat treatments that may be performed after implanting the region 156 may be considered inappropriate. Any excess material of the layers 165 and 166 may be removed, for instance, by CMP, etching and the like, as discussed above.

FIG. 1f schematically illustrates the semiconductor device 100 when exposed to an etch ambient 106, in which the mask material 120 may be removed selectively with respect to the gate electrode structure 160, the spacer structure 155 and the drain and source regions 151. For this purpose, a plurality of selective etch recipes are available and may be used during the etch process 106. For example, silicon dioxide may be efficiently removed selectively with respect to a plurality of metal materials and selectively to a silicon material and silicon nitride, which may be used in the spacer structure 155. In other cases, while elevated temperatures may not be required during the previous processing, the material 120 may be provided in the form of any appropriate polymer material, which may be removed on the basis of an oxygen plasma, wet chemical etch recipes and the like. In still other illustrative embodiments, the material 120 may be provided in the form of an amorphous carbon material, thereby enabling applying any required heat treatment after implanting the region 156, while, on the other hand, the removal of the amorphous carbon material may be efficiently accomplished on the basis of oxygen plasma recipes, thereby substantially not affecting other device areas. Consequently, after removing the mask layer 120, the further processing may be continued, for instance, by forming metal silicide regions in accordance with well-established manufacturing techniques, followed by the deposition of appropriate interlayer dielectric material, as is also previously explained.

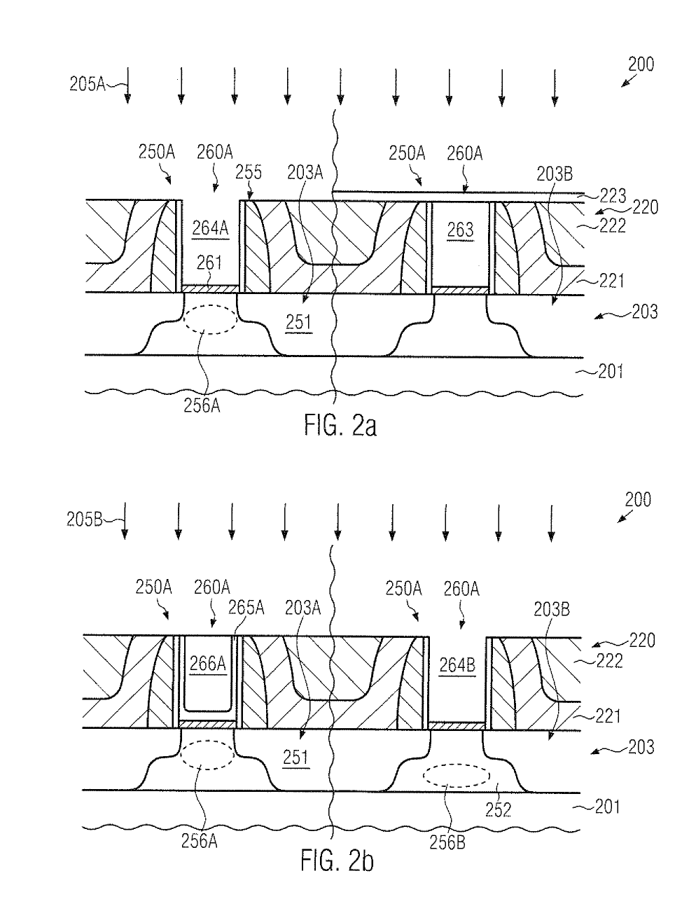

With reference to FIGS. 2a-2b, further illustrative embodiments will now be described in which gate openings or trenches may be formed in separate etch processes so that dopant species may be incorporated into one active region, while the placeholder electrode material in the other gate electrode structure may be used as an implantation mask.

FIG. 2a schematically illustrates a cross-sectional view of a semiconductor 200 comprising a substrate 201 and a semiconductor layer 203. With respect to these components, the same criteria apply as previously explained with reference to the semiconductor device 100. Furthermore, active regions 203A, 203B may be provided in the semiconductor layer 203, for instance on the basis of isolation structures, as is also previously discussed with reference to the device 100. A first transistor 250A may be formed in and above the active region 203A and a second transistor 250B may be formed in and above the active region 203B. In the embodiment shown, the transistors 250A, 250B may have substantially the same basic configuration, such as the length, transistor width, conductivity type and the like, while, on the other hand, these transistors are to receive different characteristics, for instance with respect to threshold voltage and/or body resistance, based on a self-aligned well implantation, as is also described with reference to the device 100. In the manufacturing stage shown, the transistors 250A, 250B comprise gate electrode structures 260A, 260B, respectively, comprising a gate dielectric material 261 and a placeholder material 263, which, however, may already have been removed in the gate electrode structure 260A, thereby forming a gate opening or trench 264A therein. Furthermore, on sidewalls of the gate electrode structures 260A, 260B, a spacer structure 255 of any appropriate configuration may be provided, as is also discussed above. Moreover, drain and source regions 251 may be formed in the active regions 203A, 203B and may have a similar configuration with respect to profile and dopant concentrations. Moreover, if required, metal silicide regions (not shown) may be formed therein, depending on the overall process strategy. Additionally, a mask material 220, such as a portion of an interlayer dielectric material may be formed laterally adjacent to the gate electrode structures 260A, 260B. For example, the mask layer 220 may comprise two or more different materials, such as materials 221, 222, one of which or both may be provided with a high internal stress level so as to induce a certain type of strain in the channel regions 203A, 203B. Moreover, an additional mask layer 223 may be formed so as to cover the transistor 250B.

The semiconductor device 200 may be formed on the basis of any appropriate process technique, as is also described above with reference to the semiconductor device 100. For example, the active regions 203A, 203B may be formed on the basis of a common well implantation so as to provide basic transistor characteristics, while, in other cases, a substantially non-doped material may be used, if appropriate dopant profiles may be established on the basis of a late well implantation process or process sequence. Generally, the gate electrode structures 260A, 260B may be formed on the basis of any appropriate process technique, wherein, if required, a high-k dielectric material may be incorporated in the gate insulation layer 261. After completing the basic transistor configuration, which may also include the formation of metal silicide regions, as is for instance described above, the material 220 may be formed by any appropriate deposition technique, and thereafter the layer 220 may be planarized, thereby exposing a surface of the placeholder material 263, as is also described above with reference to the device 100. Thereafter, the mask layer 223 may be formed, for instance, by depositing a silicon dioxide material or any other appropriate mask material and patterning the same on the basis of a lithography process. Next, the placeholder material 263 may be removed from the gate electrode structure 260A, thereby forming the gate opening 264A. Subsequently, an implantation process 205A may be performed to incorporate a well dopant species, thereby forming a locally restricted implantation region 256A in the active region 203A in order to adjust the overall transistor characteristics, such as threshold voltage and the like. With respect to the implantation process 205A, the same criteria apply as previously explained with reference to the device 100. On the other hand, the placeholder material 263 may efficiently avoid penetration of the active region 203B. After the implantation process 205A, the further processing may be continued by depositing any appropriate materials for the gate electrode structure 260A, such as a work function metal and an actual electrode metal, and corresponding excess materials may be efficiently removed, for instance by CMP and the like. Moreover, the mask material 223 may also be removed, thereby exposing the placeholder material 263 of the gate electrode structure 260B. Next, the material 263 may be removed by using any appropriate etch chemistry, while the layer 220 and any metal materials in the gate electrode structure 260A may act as efficient etch stop materials. It should be appreciated that a plurality of metals may have a high etch resistivity with respect to wet chemical etch recipes, which are appropriate for efficiently removing silicon-based materials.

FIG. 2b schematically illustrates the semiconductor device 200 in a manufacturing stage in which metal-containing materials 265A, 266A are provided in the gate electrode structure 260A, for instance in the form of a work function metal species and a fill metal, while the gate electrode structure 260B may have formed therein the gate opening 264B. Moreover, an implantation process 205B may be performed to incorporate an appropriate species in the active region 203B for adjusting transistor characteristics in accordance with design requirements. In the example shown, an implantation region 256B may be formed at an appropriate depth, for instance in order to reduce the overall resistance of a body region 252, as is also previously explained. To this end, process parameters of the implantation process 205B may be appropriately selected so as to position the maximum concentration of the region 256B at the desired depth level. On the other hand, the gate electrode structure 260A may act as an efficient implantation mask, thereby avoiding undue incorporation of the implantation species in the active region 203A. Thereafter, the further processing may be continued by depositing appropriate metal-containing materials so as to fill the gate opening 264B and, if required, any additional heat treatments, compatible with the state of the device 200, may be performed. It should be appreciated that if different materials are required for the gate electrode structures 260A, 260B, for instance in adjusting a different work function and the like, the above-described strategy may provide significant advantages in view of superior deposition conditions, since a single work function metal may be provided in each of the gate electrode structures 260A, 260B, thereby not unduly reducing the width of the corresponding gate openings, while a common fill electrode material may be subsequently provided, thereby avoiding undue deposition-related irregularities.

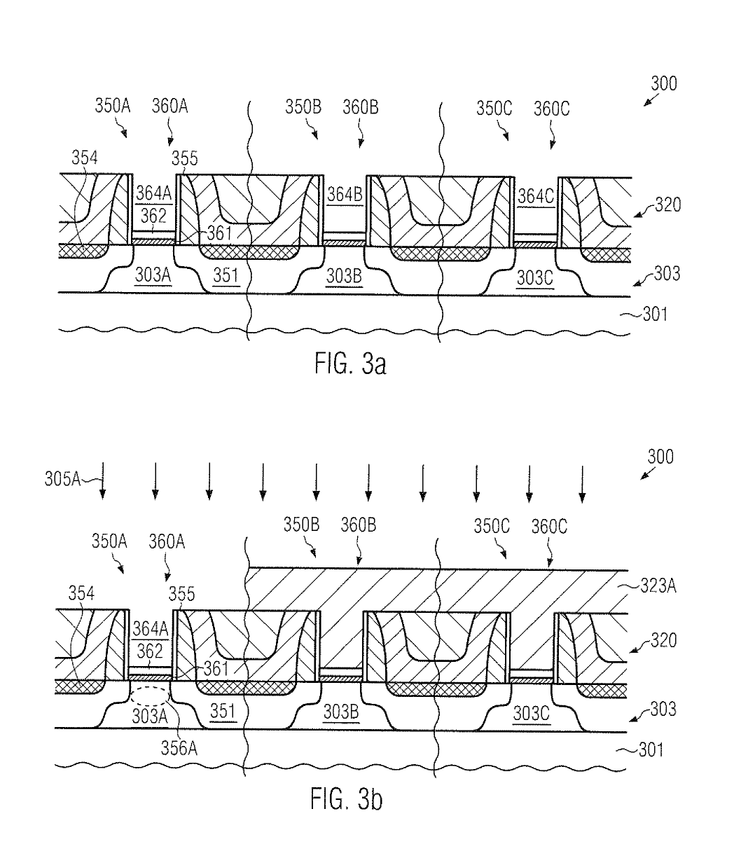

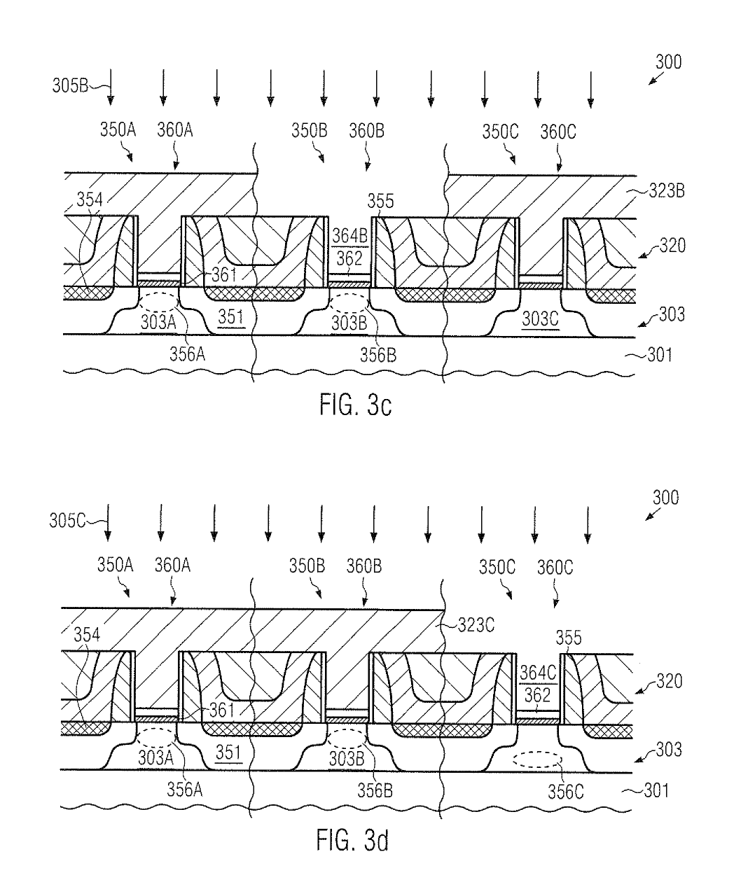

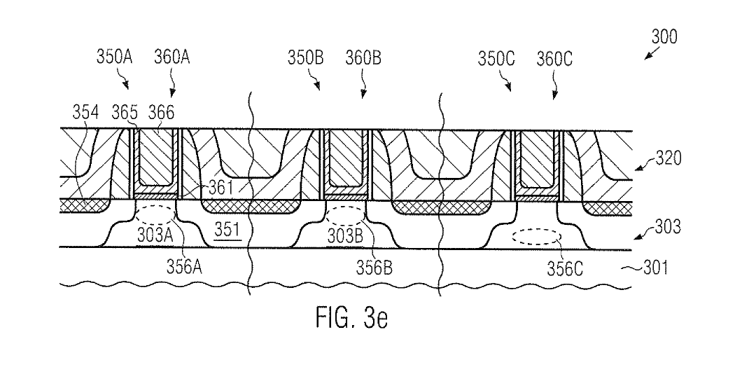

With reference to FIGS. 3a-3e, further illustrative embodiments will now be described in which a plurality of gate openings may be formed concurrently, thereby providing a highly efficient process flow, while nevertheless different implantation regions may be provided for the various gate electrode structures.

FIG. 3a schematically illustrates a semiconductor device 300 comprising a substrate 301 and a semiconductor layer 303, in which a plurality of active regions 303A, 303B and 303C may be provided. In and above the active regions 303a, . . . , 303c transistors 350a, 350b, and 350c may be formed, which may represent transistors having the same basic transistor configuration, while at the same time requiring different characteristics, for instance in view of threshold voltage, body resistance and the like. Furthermore, in the manufacturing stage shown, the transistors may comprise drain and source regions 351, possibly in combination with metal silicide regions 354 and gate electrode structures 360A, 360B, 360C may be provided and may comprise, in the manufacturing stage shown, corresponding gate openings or trenches 364A, 364B, 364C, respectively. Moreover, spacer structures 355 and a mask material 320 may be provided in this manufacturing stage. It should be appreciated that, for any of these components, the same criteria may apply, as previously discussed with reference to the semiconductor devices 100 and 200. For example, the gate electrode structures 360A, 360B, 360C may comprise a gate dielectric material 361, for instance comprising a high-k dielectric material, and a conductive cap layer 362, while, in other cases, one or both of these layers may be replaced by any other appropriate material, as is also previously explained.

The semiconductor device 300 as illustrated in FIG. 3a may be formed in accordance with any appropriate process sequence for forming the transistors 350A, 350B, 350C, so as to be laterally embedded in the mask material 320, which may then be planarized in order to expose a top surface of a placeholder electrode material, as is also previously discussed. Thereafter, an etch process may be performed, thereby concurrently generating the gate openings 364A, 364B, 364C.

FIG. 3b schematically illustrates the semiconductor device 300 in a manufacturing stage in which a mask 323A may be provided so as to cover the transistors 350B, 350C and expose the transistor 350A and, thus, the gate opening 364A. The mask 323A may be provided in the form of a resist material, a polymer material or any other appropriate mask material that may be efficiently deposited and also removed without unduly affecting any other device areas. Moreover, the device 300 may be subjected to an ion implantation process 305A, in which a dopant species may be incorporated into the active region 303A through the opening 364A, thereby forming an implantation region 356A in order to appropriately adjust the characteristics of the transistor 350A. For example, by positioning the implantation region 356A with an appropriate dopant concentration at a moderate depth, the threshold voltage may be efficiently adjusted on the basis of the implantation process 305A.

FIG. 3c schematically illustrates the semiconductor device 300 in a further advanced manufacturing stage in which an implantation mask 323B may be provided so as to cover the transistors 350A, 350C, while exposing the transistor 350B and, thus, the gate opening 364B. Moreover, a further implantation process 305B may be performed to incorporate an implantation region 356B in order to appropriately adjust the characteristics of the transistor 350B. For instance, the implantation process 305B may differ in at least one process parameter, such as type of dopant species, implantation energy, dose and the like, from the implantation process 305A (FIG. 3b).

FIG. 3d schematically illustrates the semiconductor device 300 in a further advanced manufacturing stage in which an implantation mask 323C may cover the transistors 350A, 350B and may expose the transistor 350C and, thus, the gate opening 364C. Furthermore, an implantation process 305C may be applied in order to form an implantation region 356C at a desired depth and with a desired dopant concentration in order to adjust the characteristics of the transistor 350C in accordance with design requirements. Thereafter, the implantation mask 323C may be removed and the further processing may be continued by filling in appropriate material systems into the openings of the gate electrode structures 360A, 360B, 360C.

FIG. 3e schematically illustrates the semiconductor device 300, wherein the gate electrode structures 360A, 360B, 360C may comprise an electrode metal 366, such as aluminum and the like, in combination with a work function metal 365. In the embodiment shown, the gate electrode structures 360A, 360B, 360C may, thus, have the same configuration with respect to any metal-containing materials formed therein, thereby obtaining substantially the same work function for each of the gate electrode structures 360A, 360B, 360C. On the other hand, the transistor characteristics may also be influenced by various implantation regions 356A, 356B, 356C, thereby obtaining the desired different “flavors” of transistors of the same conductivity type and configuration. It should be appreciated that the above-described process sequence may also be applied to transistors of the inverse conductivity type, if different flavors may also be required. Moreover, if an additional variation of transistor characteristics may be considered necessary, different metal species may be incorporated in the various gate electrode structures 360A, 360B, 360C, for instance in terms of type and/or thickness of a work function adjusting species, thereby also affecting the resulting threshold voltage.

As a result, the present disclosure provides semiconductor devices and manufacturing techniques in which transistor characteristics, such as threshold voltage, body resistance and the like, may be adjusted with a high degree of flexibility by implanting an appropriate well dopant species in a locally restricted manner, thereby reducing or avoiding any effect in drain and source regions, and hence additionally obtaining a superior dopant profile for the drain and source regions, for instance for providing an increased depth in SOI devices and the like. The locally restricted implantation regions may be obtained by performing an implantation process through a gate opening, which thus ensures a self-aligned implantation process. The gate opening may then be refilled with any appropriate material, such as a work function metal, a highly conductive metal, wherein a high-k dielectric material may also be provided in the late manufacturing stage, if required. In other cases, the high-k dielectric material may be provided in an early manufacturing stage, possibly in combination with a work function adjusting species, and a highly conductive electrode metal may be provided after performing the late well implantation process, wherein any appropriate work function metal species may be incorporated prior to providing the electrode metal.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a gate electrode structure of a transistor on a semiconductor region, said gate electrode structure comprising a placeholder electrode material;
forming drain and source regions in said semiconductor region;
removing at least a portion of said placeholder electrode material so as to form a gate opening in said gate electrode structure;
introducing a dopant species into said semiconductor region through said gate opening; and
forming an electrode metal in said gate opening.

2. The method of claim 1, wherein said drain and source regions are formed prior to removing at least a portion of said placeholder electrode material.

3. The method of claim 1, wherein forming said gate electrode structure comprises forming a high-k dielectric material in said gate electrode structure.

4. The method of claim 1, further comprising performing an anneal process after introducing said well dopant species.

5. The method of claim 1, wherein forming an electrode metal in said gate opening comprises removing said placeholder electrode material, forming a work function metal in said gate opening and forming a fill metal in said gate opening.

6. The method of claim 1, wherein introducing said dopant species through said gate opening comprises forming a shallow implantation region below a channel region of said transistor.

7. The method of claim 1, wherein introducing said dopant species through said gate opening comprises forming a deep implantation region so as to reduce a body resistance of said transistor.

8. The method of claim 1, further comprising forming metal silicide regions in said drain and source regions prior to removing at least said portion of said placeholder electrode material.

9. The method of claim 1, further comprising forming metal silicide regions in said drain and source regions after removing at least said portion of said placeholder electrode material.

10. A method, comprising:
forming a first gate electrode structure above a first semiconductor region and a second gate electrode structure above a second semiconductor region of a semiconductor device, said first and second gate electrode structures comprising a placeholder electrode material;
forming a first gate opening in said first gate electrode structure by removing at least a portion of said placeholder electrode material in said first gate electrode structure;
forming a second gate opening in said second gate electrode structure by removing at least a portion of said placeholder electrode material in said second gate electrode structure;
introducing dopant species into at least one of said first and second semiconductor regions through at least one of said first and second gate openings; and
filling an electrode metal in said first and second gate openings.

11. The method of claim 10, wherein said first gate opening and said second gate opening are formed by performing a common etch process.

12. The method of claim 11, wherein introducing a dopant species into at least one of said first and second semiconductor regions comprises forming an implantation mask so as to cover said second gate opening and performing a first implantation process based on a first parameter setting.

13. The method of claim 12, further comprising removing said first implantation mask and forming a second implantation mask so as to cover said first gate opening and performing a second implantation process based on a second parameter setting that differs from said first parameter setting.

14. The method of claim 10, wherein forming said first and second gate openings comprises selectively removing at least a portion of said placeholder material from said first gate electrode structure and preserving said placeholder material in said second gate electrode structure.

15. The method of claim 14, further comprising introducing a dopant species into said first semiconductor region through said first gate opening and refilling said gate opening with a first electrode metal prior to forming said second gate opening.

16. The method of claim 10, further comprising forming a dielectric material adjacent to said first and second gate electrode structures prior to forming said first and second gate openings and preserving at least a portion of said dielectric material during the further processing of said semiconductor device.

17. The method of claim 10, wherein forming said first and second gate electrode structures comprises forming a high-k dielectric material in said first and second gate electrode structures.

18. A semiconductor device, comprising:
a gate electrode structure of a transistor formed on a semiconductor region, said semiconductor region having a first length;
drain and source regions formed in said semiconductor region;
a body region formed in said semiconductor region and laterally separating said drain and source regions; and
an implantation region formed in said semiconductor region by a specific dopant species and having a second length that is less than said first length.

19. The semiconductor device of claim 18, wherein said gate electrode structure comprises a high-k dielectric material and an electrode metal.

20. The semiconductor of claim 19, wherein said implantation region is positioned at a depth level in said body region so as to determine one of a threshold voltage and a body resistance of said transistor.
